(19) United States
(12) Patent Application Publication
(10) Pub. No.: US 2009/0278585 A1
(43) Pub. Date: Nov. 12, 2009

(54) ATTENUATION SYSTEM AND METHOD

(75) Inventor: SONG LI, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD ., Shenzhen City (CN); HON HAI PRECISION INDUSTRY CO., LTD., Tu-Cheng (TW)

(21) Appl. No.: 12/189,803

(22) Filed: Aug. 12, 2008

(30) Foreign Application Priority Data
May 8, 2008 (CN) 200810301470.6

(51) Int. Cl. H03K 5/08

(52) U.S. Cl. 327/330

(57) ABSTRACT

An attenuation system includes an attenuator, a control unit, a comparator, two couplers, and two convert circuits, wherein a signal is attenuated by the attenuator via the first coupler and sent to a functional unit. The signal is output to the first convert circuit via the first coupler to be converted to a first digital signal. The first digital signal is output to a first input end of the comparator. The damped signal is output to the second convert circuit via the second coupler to be converted to a second digital signal. The second digital signal is output to a second input end of the comparator. The comparator compares the first digital signal and the second digital signal, and transmits a factual decrement to the control unit. The control unit compares the factual decrement and the preset decrement, and accordingly adjusts the parameter of the attenuator.

### BACKGROUND OF THE INVENTION

1. Field of the Invention

Embodiments of the present disclosure relate to attenuators, and more particularly to an attenuation system and a method.

2. Description of Related Art

An attenuator is an electronic device that reduces the amplitude or power of a signal without appreciably distorting the waveform of the signal. Attentuators are used to lower the amplitude of the signal by a predetermined amount to enable measurements or to protect the measuring device from signal levels that might damage it.

Referring to FIG. 2, an attenuation system includes an attenuator 1 and a control unit 2. An input signal is attenuated by the attenuator 1. The control unit 2 is connected to the attenuator 1 to adjust the loss of the attenuator 1. Because the reliability of the attenuator 1 will change with temperature, the attenuation system is inaccurate.

### SUMMARY

An exemplary attenuation system includes an attenuator, a control unit, a comparator, a first coupler, and a second coupler. The attenuator includes an input end, an output end, and a control end. The control unit is connected to the control end of the attenuator for adjusting a loss of the attenuator. The comparator includes a first input end, a second input end, and a control end. The control end of the comparator is electrically connected to the control unit. The first coupler includes an input end, a first output end, and a second output end. The input end of the first coupler is configured to receive the electrical signal. The first output end of the first coupler is connected to the first input end of the comparator via a first convert circuit to output a first digital signal to the comparator. The second output end of the first coupler is connected to the input end of the attenuator to output the electrical signal to the attenuator to be attenuated. The first convert circuit converts the electrical signal into the first digital signal. The second coupler includes an input end, a first output end, and a second output end. The input end of the second coupler is connected to the output end of the attenuator to receive a damped signal from the attenuator. The first output end of the second coupler is connected to the second input end of the comparator via a second convert circuit to output a second digital signal to the comparator. The second output end of the second coupler is connected to a functional unit to output the damped signal to the functional unit. The second convert circuit converts the damped signal into the second digital signal.

Other advantages and novel features will become more apparent from the following detailed description when taken in conjunction with the accompanying drawings, in which:

### BRIEF DESCRIPTION OF THE DRAWINGS

FIG. 1 is a block diagram of one embodiment of an attenuation system in accordance with the present disclosure; and

FIG. 2 is a block diagram of a conventional attenuation system.

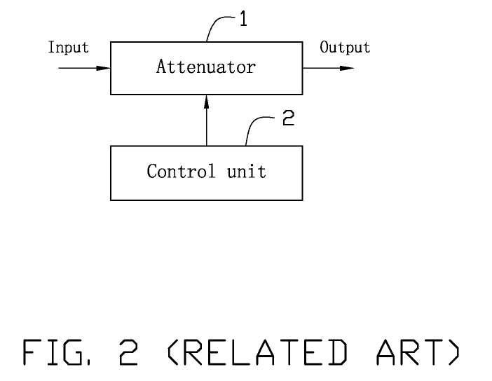

### DETAILED DESCRIPTION

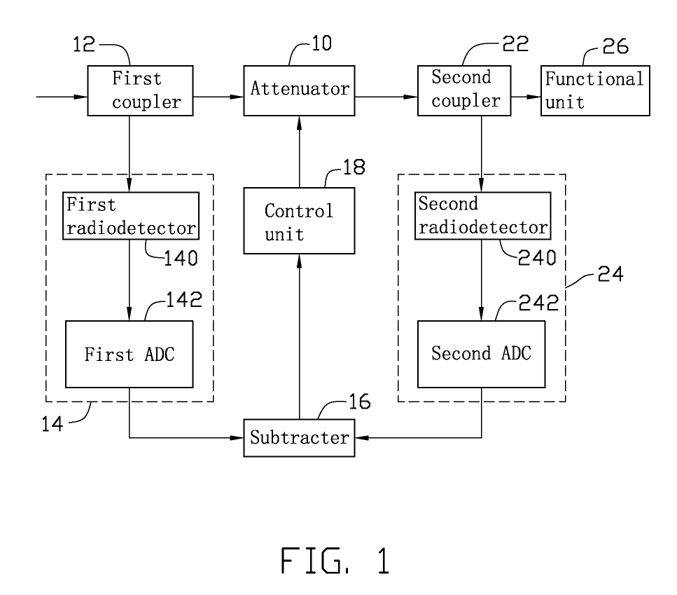

Referring to FIG. 1, an attenuation system in accordance with an embodiment of the present disclosure includes an attenuator 10, a first coupler 12, a second coupler 22, a first convert circuit 14, a second convert circuit 24, a comparator such as a subtracter 16, and a control unit 18. The first convert circuit 14 includes a first radiodetector 140 and a first analog-to-digital converter (ADC) 142. The second convert circuit 24 includes a second radiodetector 240 and a second ADC 242.

The attenuator 10 includes an input end, an output end, and a control end. The subtracter 16 includes a first input end, a second input end, and an output end. The control unit 18 includes an input end and an output end. An input end of the first coupler 12 is configured to receive an electrical signal. A first output end of the first coupler 12 is electrically coupled to the input end of the attenuator 10. A second output end of the first coupler 12 is electrically coupled to the first input end of the subtracter 16 via the first radiodetector 140 and the first ADC 142 in sequence. An input end of the second coupler 22 is electrically coupled to the output end of the attenuator 10. A first output end of the second coupler 22 is electrically coupled to the second input end of the subtracter 16 via the second radiodetector 240 and the second ADC 242 in sequence. A second output end of the second coupler 22 is electrically coupled to a functional unit 26 to output a damped signal to the functional unit 26. The output end of the subtracter 16 is electrically coupled to the input end of the control unit. The output end of the control unit is electrically coupled to the control end of the attenuator. Depending on the embodiment, the functional unit may comprise one or more resistors, capacitors, inductors, transistors, or integrated circuits.

The first coupler 12 divides an input signal into two input signals comprising a first input signal and a second input signal. The first input signal is converted to the damped signal by the attenuator 10. The second input signal is converted to a first digital signal by the first radiodetector 140 and the first ADC 142, and then is transmitted to the first input end of the subtracter 16. The damped signal is divided into two output signals via the second coupler 22. A first output signal is transmitted to the functional unit 26. A second output signal is converted to a second digital signal by the second radiodetector 240 and the second ADC 242, and then is transmitted to the second input end of the subtracter 16. The subtracter 16 compares a voltage of the first digital signal and a voltage of the second digital signal, and then gets a factual decrement between the voltage of the first digital signal and the voltage of the second digital signal. It may be understood that factual decrement refers to a difference between the voltage of input signal and the voltage of the damped signal. The control unit 18 compares the factual decrement and a preset decrement, and adjusts the loss of the attenuator 10 accordingly to achieve the preset decrement.

In one embodiment, the first radiodetector 140, the first ADC 142, the second radiodetector 240, and the second ADC 242 are configured to convert a voltage signal to a digital signal. In other embodiments, they can be replaced by other converting components, such as an integrated circuit (IC) chip which can convert the voltage signal to the digital signal.

The foregoing description of the embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the disclosure and their practical application so as to enable others of ordinary skills in the art to utilize the disclosure and various embodiments and with various modifications as are suited to the particular use contemplated. Alternative embodiments will become apparent to those skilled in the art to which the present disclosure pertains without departing from its spirit and scope. Accordingly, the scope of the present disclosure is defined by the appended claims rather than the foregoing description and the embodiments described therein.

1. An attenuation system for attenuating an electrical signal, comprising:
an attenuator comprising an input end, an output end, and a control end;
a comparator comprising a first input end and a second input end;
a first coupler comprising an input end, a first output end, and a second output end, wherein the input end of the first coupler is configured to receive the electrical signal, the first output end of the first coupler is connected to the first input end of the comparator via a first convert circuit to output a first digital signal to the comparator, and the second output end of the first coupler is connected to the input end of the attenuator to output the electrical signal to the attenuator to be attenuated, wherein the first convert circuit converts the electrical signal into the first digital signal;
a second coupler comprising an input end, a first output end, and a second output end, wherein the input end of the second coupler is connected to the output end of the attenuator to receive a damped signal from the attenuator, the first output end of the second coupler is connected to the second input end of the comparator via a second convert circuit to output a second digital signal to the comparator, and the second output end of the second coupler is to output the damped signal, wherein the second convert circuit converts the damped signal into the second digital signal, wherein the comparator compares the first and second digital signals to obtain a factual loss of the attenuator; and.
a control unit connected to the control end of the attenuator for adjusting a loss of the attenuator to achieve a preset loss according to the factual loss of the attenuator from the comparator.

2. The attenuation system as claimed in claim 1, wherein the first convert circuit comprises a first radiodetector and a first analog-digital convertor (ADC), the second convert circuit comprises a second radiodetector and a second ADC; the first radiodetector and the first ADC is connected in sequence between the first output end of the first coupler and the first input end of the comparator, and the second radiodetector and the second ADC is connected in sequence between the first output end of the second coupler and the second input end of the comparator.

3. The attenuation system as claimed in claim 1, wherein the comparator is a subtracter.

4. (canceled)

5. A method for attenuating a signal with a preset decrement comprising:
providing:
an attenuator, a control unit, a comparator, a first coupler, a second coupler, a first convert circuit, and a second convert circuit;
wherein the signal is attenuated by the attenuator via the first coupler to form a damped signal; the signal is output to the first convert circuit via the first coupler to be converted to a first digital signal, and the first digital signal is output to a first input end of the comparator; the damped signal is output to the second convert circuit via the second coupler to be converted to a second digital signal, and the second digital signal is output to a second input end of the comparator; the comparator compares the first digital signal and the second digital signal, and transmits a factual decrement to the control unit; the control unit compares the factual decrement and the preset decrement, and adjusts the parameter of the attenuator to the preset decrement.

6. The method for attenuating a signal with a preset decrement as claimed in claim 1, wherein the first convert circuit comprises a first radiodetector and a first analog-digital convertor (ADC), the second convert circuit comprises a second radiodetector and a second ADC.

7. The method for attenuating a signal with a preset decrement as claimed in claim 1, wherein the comparator is subtracter.

8. (canceled)
